(19) United States
(12) Patent Application Publication
(10) Pub. No.: US 2024/0186250 A1
(43) Pub. Date: Jun. 6, 2024

(54) Microelectronic Assembly Including Interconnect Bridges with Through Vias Embedded Therein

(71) Applicant: Intel Corporation, Santa Clara, CA (US)

(72) Inventors: Jeremy D. Ecton, Gilbert, AZ (US); Brandon Christian Marin, Gilbert, AZ (US); Srinivas V. Pietambaram, Chandler, AZ (US); Tarek A. Ibrahim, Mesa, AZ (US); Suddhasattwa Nad, Chandler, AZ (US); Gang Duan, Chandler, AZ (US); Haobo Chen, Chandler, AZ (US); Hiroki Tanaka, Gilbert, AZ (US)

(73) Assignee: Intel Corporation, Santa Clara, CA (US)

(21) Appl. No.: 18/061,188

(22) Filed: Dec. 2, 2022

(51) Int. Cl. H01L 23/538; H01L 21/48

(52) U.S. Cl. CPC H01L 23/5381; H01L 21/486; H01L 23/5384; H01L 23/5386

(57) ABSTRACT

A microelectronic assembly includes a substrate comprising: a panel including glass and defining an opening therein; an interconnect bridge (IB) in the opening and including interconnect pathways and IB through vias (IBTVs); and electrically conductive structures at a lower surface of the substrate to electrically couple the substrate to another component, at least some of the electrically conductive structures coupled to the IBTVs to form respective vertical electrical connections between the lower surface of the substrate and an upper surface of the substrate; and an electronic component (EC) layer on the upper surface of the substrate, the EC layer including a first active EC (AEC) and a second AEC electrically coupled to one another through the interconnect pathways, at least one of the first AEC or the second AECs further electrically coupled to one or more of the at least some of the electrically conductive structures.

### TECHNICAL FIELD

This disclosure relates generally to die-to-die (D2D) in-package interconnect technology.

### BACKGROUND

In-package die-to-die (D2D) interconnect technologies include, at a high level, interconnect regimes to provide signal connection between two dies provided on a top surface of a substrate. A standard interconnect regime involves the provision of signal routing traces typically within organic build-up layers of a substrate to couple the two dies to one another. A more advanced interconnect regime provides a silicon bridge structure embedded within a substrate, where the silicon bridge structure includes interconnect pathways therein to electrically couple the two dies to one another. An example of a silicon bridge structure for an advanced package interconnect regime includes, for example, an embedded multi-die interconnect bridge (EMIB), or a chip-on-wafer-on-substrate (CoWoS). A given D2D interconnect technology or regime may be selected based on a number of factors, such as, for example, bandwidth density requirements (e.g. bandwidth per millimeter (BW/mm) and/or BW/mm 2), a die/package desired floorplan, and available form factors.

The demand for increased performance and reduced form factor are driving packaging architectures towards multi-chip integration architectures. Multi-chip integration allows for dies manufactured at different process nodes to be implemented into a single electronic package, for example interconnected through an EMIB. However, current multi-chip architectures result in larger form factors that are not suitable for some use cases or are not otherwise desirable to end users.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 is a cross sectional image of a microelectronic assembly according to a first embodiment.

FIG. 2 is a cross sectional image of a microelectronic assembly according to a second embodiment.

FIG. 3 is a cross sectional image of a microelectronic assembly according to a third embodiment.

FIG. 4 is a cross sectional image of a microelectronic assembly according to a fourth embodiment.

FIGS. 5A-5D are cross-sectional views of temporary microelectronic configurations in stages of fabrication to fabricate a microelectronic assembly of any one of FIG. 1, 3, or 4.

FIGS. 6A-6E are cross-sectional views of temporary microelectronic configurations in stages of fabrication starting from the microelectronic configuration of FIG. 5D to fabricate a microelectronic assembly of FIG. 1.

FIGS. 7A-7F are cross-sectional views of temporary microelectronic configurations in stages of fabrication starting from the microelectronic configuration of FIG. 5D to fabricate a microelectronic assembly of FIG. 4.

FIG. 8 is a flow chart of a process according to some embodiments.

FIG. 9 is a cross-sectional side view of an integrated circuit device assembly that may include a microelectronic structure in accordance with any of the embodiments disclosed herein.

FIG. 10 is a block diagram of an example electrical device that may include a microelectronic structure, in accordance with any of the embodiments disclosed herein.

### DETAILED DESCRIPTION

Current semiconductor packaging solutions sometimes use multi-die architectures. However, the inclusion of multiple dies in a single package is not without issue. In addition to the larger footprint of existing multi-die architectures, such systems also suffer from poor yield and reliability. Particularly, the interconnections between dies are difficult to control due to warpage and other alignment issues when using traditional packaging substrates.

Some embodiments provide a microelectronic assembly including a substrate and active electronic components (AECs) supported on an upper or top surface of the substrate. The panel layer including glass may support an interconnect bridge in a cavity or opening thereof. The interconnect bridge may have through vias therein to allow the electrical coupling of the AECs to an underlying substrate that is to support the microelectronic assembly on an upper surface thereof. The through vias of the interconnect bridge may be configured to supply power through the interconnect bridge to the AECs. The interconnect bridge may also have interconnect pathways therein through which the AECs are interconnected. An embodiment allows fine bump pitch die-to-die tiling, high interconnect density, z dimension disaggregation of dies from a package substrate, in this manner allowing device level rather than wafer level attachment of dies to package substrate, and this packaging of a much higher yield than packaging that involves wafer level attachment.

The demand for miniaturization of form factor (such as die contact pitches substantially equal to or lower than 25 microns) and increased levels of integration for high performance are driving sophisticated packaging approaches in the semiconductor industry. Die partitioning enables miniaturization of small form factor and high performance without yield issues seen with other methods, but needs fine die to die interconnections. Embedded Multi-die Interconnect Bridge (EMIB) pioneered and developed by Intel, is a breakthrough technology that enables a lower cost and simpler 2.5D packaging approach for very high-density interconnects (e.g., pitches of about 25 microns or less) between heterogeneous dies on a single package. Instead of an expensive silicon interposer with TSV (through silicon via), with EMIB, a small silicon bridge chip is embedded in the package, enabling very high density die-to-die connections only where needed. Standard flip-chip assembly is used however for robust power delivery and to connect high-speed signals directly from chip to the package substrate.

A patch can be simplified to have no multiple redistribution layer (RDL) routing or fanout layers due to assembly concerns of attaching the patch to the bottom substrate (mid-level interconnect, MLI). While mass reflow is not feasible, significant flattening issues that arise due to the stack warpage can result in a very narrow Thermal Compression Bonding (TCB) attach window.

Some embodiments pertain to future generations of die partitioning, where one or more interconnect bridges can interconnect the dies (or AECs, such as IC dies, memory dies, etc.) at finer bump pitches of about 25 microns or lower than those currently delivered by existing interconnect bridges.

The existing interconnect bridge (e.g., EMIB) approach suffers from a high cumulative Bump Thickness Variation (BTV) and as the number of bridges to be embedded increase, cost of embedding and yields will suffer. Alternate architectures and/or approaches have been proposed. One such technology involves multiple dies face-to-face coupled to a base die (vertically), and the base die coupled to a package substrate. Another such technology involves an interconnect bridge with through silicon vias (e.g., EMIB-T) in the form of an active die instead of a standard bridge with no TSV connections. Another option for enabling fine die-to-die interconnections is incorporating a thin glass core into the package substrate. A glass core compared to a conventional organic (e.g., epoxy) core offers several advantages including a higher plated through hole (e.g., through via) density, lower signal losses, lower total thickness variation (TTV), among others.

Some embodiments explore the possibility of glass being used in patch architectures with the potential for direct hybrid bonding of contacts on glass with contacts of dies being supported thereon, based on the relatively low TTV and good dimensional stability of glass.

Multiple embodiments of glass patch architectures are proposed wherein, which benefit from the low TTV and dimensional stability of glass as well as the high aspect ratio patterning capability of glass, for example using conventional laser assisted glass patterning techniques.

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

The technologies described herein may be implemented in one or more electronic devices. Non-limiting examples of electronic devices that may utilize the technologies described herein include any kind of mobile device and/or stationary device, such as microelectromechanical systems (MEMS) based electrical systems, gyroscopes, advanced driving assistance systems (ADAS), 5G communication systems, cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments, the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of in electronic devices, including semiconductor packages with passive heat spreaders, interface layers, TIMs, top dies, side dies, substrates, and package substrates.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

As used herein, reference to a “die” is meant to broadly refer to a die, a chiplet, a chip complex, a chiplet complex, or any other integrated circuit structure including circuitry therein supported on a substrate. While the terms die, chip, and chiplet may be used interchangeably, the term chiplet is sometimes used to refer to an integrated circuit die that implements a subset of the functionality of a larger integrated circuit component, the larger integrated circuit component formed using one or more chiplets connected by inter-die interconnects (e.g., interposers, bridges, local interconnect components, local silicon interconnects). The use of chiplets in integrated circuit components has become attractive as feature sizes have reduced and the demand for high-performance larger integrated circuit components has increased. The approach of assembling multiple known-good dies (chiplets) to form a larger integrated circuit component results in improved manufacturing efficiencies as the overall yield of an integrated circuit component assembled from multiple small chiplets is better than that of an integrated circuit component in which the functionality of the chiplets is implemented on a single large integrated circuit die. Any integrated circuit die, chip, or chiplet can implement any portion of the functionality of any processor unit described or referenced herein.

As used herein, the term “electronic component” can refer to an active electronic circuit/active electronic component (e.g., processing unit, die, chiplet, memory, High Bandwidth Memory (HBM), storage device, FET, etc.) or a passive electronic circuit/passive electronic component (e.g., resistor, inductor, capacitor, etc.).

As used herein, the term “the material” of component A may refer to one or to more constituent materials of component A. For example, where component A includes 3 sublayers made of three respective materials X, Y and Z, the disclosure herein may refer to “the material of component A” to refer to materials X, Y and Z that make up component A.

As used herein, the term “integrated circuit component” can refer to an electronic component on a semiconducting material configured to perform a function. An integrated circuit (IC) component can comprise one or more of any electronic components, such as any electronic components described or referenced herein, or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

As used herein, “pitch” may be measured center-to-center between two elements (e.g., from a center of a TCV to a center of an adjacent TCV).

As used herein, “contacts” may refer to electrically conductive structures of or on a first microelectronic component (e.g., an electronic component, a substrate, a panel layer, etc.) that may be electrically coupled to contacts of a second microelectronic component. Contacts may include, for example, solder balls, pads, or pins.

“Electrically conductive structures” as used herein may include an electrically conductive material such as a metal (e.g., copper, aluminum, nickel, cobalt, iron, tin, gold, silver, or combinations thereof). Examples of electrically conductive structures may include traces, which extend horizontally, and vias, which extend vertically.

As used herein, the term “electrically conductive pathway” refers to electrically conductive structures such as traces, vias, contacts, metallization layer coatings, metallization layers, contacts (e.g., solder balls, pads, pins, pillars, etc.).

As used herein, the term “interconnect pathway” refers to electrically conductive structures within an interconnect bridge including horizontally extending such structures. Interconnect pathways of an interconnect bridge include horizontal structures such as traces, as noted, but could also include vias, contacts (e.g., solder balls, pads, pins, pillars, etc.), or any structure that is to conduct electricity between two distinct locations.

“Hybrid bonding” as used herein may refer to a process involving direct metal to metal and dielectric to dielectric bonding between two electronic components. In hybrid bonding, the metallic bonds and dielectric bonds may occur without the use of solder materials, and there may be an absence of underfill material as well. Some hybrid bonding may result in metal grain interdiffusion at a hybrid bonded interface between two hybrid bonded contacts. Some hybrid bonding may make use of a dielectric material on metal contacts of a first electronic component to be hybrid bonded to a second electronic component. In such a case, a hybrid bonded connection between the first and second electronic components may include the metal, and also some elements of the dielectric material, such as at least one of silicon and oxygen. For hybrid bonding, an organic dielectric, such as polyimide (PI) may be used. In the case of the latter, the hybrid bonded connection may include the metal, and some elements of an organic dielectric material, such as PI.

By “A is embedded in B,” what is meant herein is that B at least partially covers side surfaces of A, and at most covers all surfaces of A.

A non-limiting example of an unpackaged integrated circuit component includes a single monolithic integrated circuit die (shortened herein to “die”); the die may include solder bumps attached to contacts on the die, or contacts on the die can allow the die to be hybrid bonded to other contacts on other devices, such as on a package substrate. When present on the die, the solder bumps or other conductive contacts can enable the die to be directly attached to a printed circuit board (PCB) or other substrates.

An existing example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

For convenience, a phrase referring to element “X,” where X is a reference numeral, may be used to refer to any one of elements XA-XB if elements have been disclosed as such. For example, the phrase “interconnect bridge 122” is used herein to refer to any one of interconnect bridges 122a or 122b.

For convenience, a phrase referring to elements “X,” where X is a reference numeral, may be used to refer to any one of elements XA-XB if elements XA-XB have been disclosed as such. For example, the phrase “interconnect bridges 122” is used herein to refer to the collection of interconnect bridges 122a and 122b.

Microelectronic assemblies, and related devices and methods, are disclosed herein.

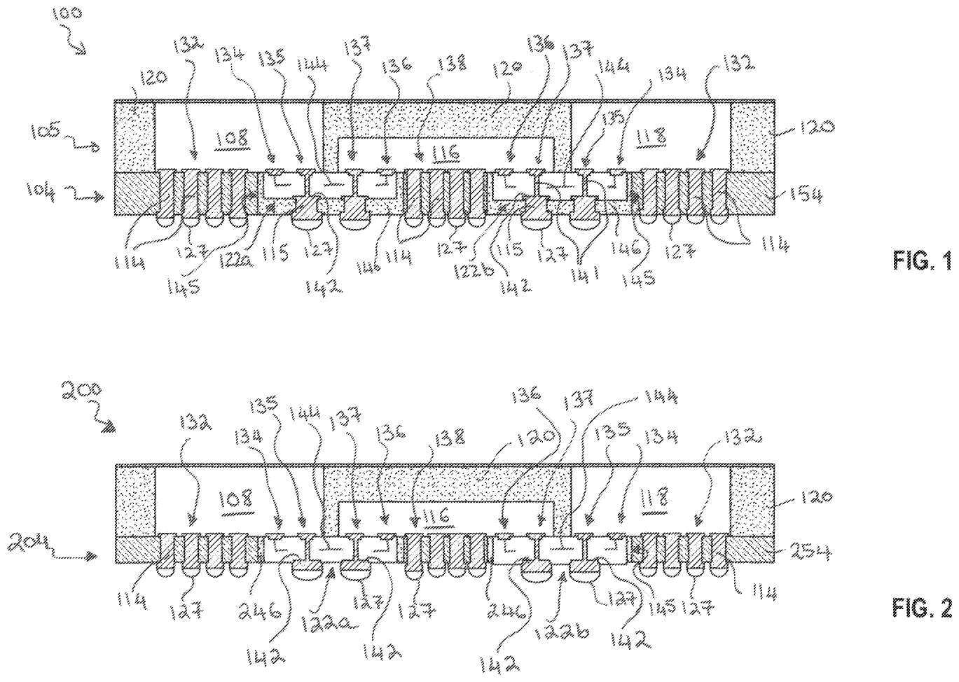

FIGS. 1-4 below show respective example embodiments of patch architectures, and are described in detail below.

FIG. 1 is a side, cross-sectional view of an example microelectronic assembly 100 in accordance with a first embodiment. Microelectronic assembly 100 includes a substrate 104 (or microelectronic structure 104) including a panel layer 154 and interconnect bridges 122a and 122b within the panel layer, the interconnect bridges encapsulated with a mold compound 146. The microelectronics assembly further includes an electronics components (EC) layer 105 that includes active electronic components (AECs) 108, 116 and 118, the EC layer electrically coupled to the substrate 104. In the shown example, AECs 108 and 118 include HBM dies (HBMs), and AEC 116 includes an integrated circuit (IC) die, and the AECs 108, 116 and 118 are shown as being encapsulated within a mold compound 120. Embodiments are not so limited, and include any AEC for dies 108, 116 and 118. For example,

For example, one or more of the AECs may include photonic integrated circuits (PICs) with waveguides/couplers (mirrors, etc.) built in glass. In such a case, the optical signals may for example travel through waveguides within the glass, such as a fiber array unit (FAU), and/or may enable PIC to PIC communication within the patch. This latter embodiment takes advantage of the fact that glass can easily accommodate optical signaling, for instance for long range transmission.

The microelectronic assembly 100 of FIG. 1 may also include electrical contacts on a bottom surface of the substrate 104, which, in the shown embodiment, include contact pads 128, and bumps, such as solder bumps 127 on contact pads 128. The solder bumps 127 may provide first level interconnects by way of example, that may allow the microelectronic assembly 100 to be electrically coupled through the solder bumps 127 with a package substrate (in which case the substrate 104 would be serving as an interposer, and a combination of the microelectronic assembly 10 and the package substrate will be referred to herein as a microelectronic package). The microelectronic package thus formed may in turn be coupled to a circuit board, such as a printed circuit board (PCB) or a motherboard, to form an integrated circuit (IC) device component therewith. Alternatively, solder bumps 127 may allow the microelectronic assembly 100 to be directly coupled to PCB or motherboard (in which case the substrate 104 may itself serve as a package substrate). Instead of solder bumps 127, according to embodiments, other contacts may be provided for the substrate 104, such as pads or pins, by way of example.

Although not shown in the embodiments of FIGS. 1, 3 and 4, according to one embodiment, one or more RDLs may be added between the solder bumps 127 (or other contacts such as pads, pins, etc.) and EMIB/AEC connections for fan out, etc. as needed.

Substrate 104 includes a panel layer 154, and, although not shown, may also include build-up layers at a bottom surface thereof. The build-up layers if provided may include successive non-conductive layers and successive metal layers (or redistribution layers (RDLs); e.g. M1, M2, . . . Mn) between the non-conductive (e.g. dielectric) layers. RDLs may correspond to interconnects including traces and vias extending through the build-up layers to conduct electrical signals therethrough.

The panel layer 154 may include a glass material. For example, the panel layer may correspond to a glass panel layer. A glass panel layer as compared to a conventional epoxy panel layer may offer several advantages, including a higher plated through hole (PTH) density, lower signal losses, lower total thickness variation (TTV), more material stability and hence lower susceptibility to warpage during semiconductor manufacturing, among others.

Electrically conductive structures of the panel layer may include vias, such as through vias 114, and such as horizontal traces (not shown). Through vias 114 extend through panel layer 154 to contact pads 132 of the HBMs 108 and 118, and to contact pads 138 of die 116, and may provide signal communication between corresponding solder bumps 127 and AECs 108, 116 and 118.

Electrically conductive structures of the substrate 104 associated with the interconnect bridges 122a and 122b but not within the interconnect bridges 122a and 122b may include through vias 115 extending through mold compound 146 to contact pads 142 of the interconnect bridges 122a and 122b. Through vias 115 may provide power to the bridges 122 by way of corresponding solder bumps 127.

Electrically conductive structures of the substrate 104 may provide signal and power communication through substrate 104 from another circuit board (e.g., a package substrate, a PCB/motherboard) electrically coupled to solder bumps 127.

Interconnect bridges 122a and 122b are shown, in this first embodiment as seen in FIG. 1, as being provided within respective openings (or cavities) 145 defined in the panel layer 154. In the shown embodiment, the openings 145 are through holes defined in the panel layer 154 within which mold compound 146 encapsulates the interconnect bridges 122. The mold compound 146 extends below a lower surface of the interconnect bridges 122. Through vias 115 extend through the mold compound 146 to reach the interconnect bridges 122. The interconnect bridges have respective upper surfaces that are substantially coextensive with an upper surface of the panel layer. Contact pads of the interconnect brides on an upper surface thereof are further substantially coextensive with contact pads on the upper surface of the panel layer.

Interconnect bridges 122 may, for example, include silicon, and may correspond, by way of example, to EMIB devices, although embodiments are not so limited. Pitches between contact pads at an upper surface of the interconnect bridges may be smaller than pitches between contact pads at an upper surface of the panel layer.

Referring back to mold compound 146, the ability to use it allows flexibility in the thickness of the panel layer 154, in that it can be as thick as needed for manufacturability and/or supporting AECs thereon, while still allowing the embedding therein of interconnect bridges of smaller and possibly of varying thicknesses, as the mold will compensate for the thickness differences.

Interconnect pathways 144 including bridge traces and bridge vias are further provided within interconnect bridges 122, and are coupled to its contact pads. An interconnect bridge 122 electrically couples, through interconnect pathways 144, two AECs together. Interconnect bridge 122a electrically couples HBM 108 and die 116, while interconnect bridge 122b electrically couples die 116 and HBM 118. AECs 108, 116 and 118 may be hybrid bonded to contact pads on through vias 114 of panel layer 154 through contact pads 132 of HBMs 106 and 118 and through contact pads 138 of die 116. AECs 108 and 116 may be electrically coupled to one another through interconnect pathways 144 of interconnect bridge 122a by being hybrid bonded, through their contact pads 134 and 136, respectively, to corresponding contact pads of interconnect bridge 122a. AECs 116 and 118 may be electrically coupled to one another through interconnect pathways 144 of interconnect bridge 122b by being hybrid bonded, through their contact pads 136 and 134, respectively, to corresponding contact pads of interconnect bridge 122b. In addition, AECs 108, 116 and 118 may be electrically coupled to electronic components outside of the shown microelectronic assembly 100 by way of interconnect bridge through vias (IBTVs) 141, namely by being hybrid bonded, through their contact pads 135 (HBMs) and 137 (die) to corresponding contacts of interconnect bridges 122. The IBTVs may for example route power to the interconnect bridges and directly to the associated AECs. For the latter reason, the through vias 115 may have a larger cross sectional area in a plane extending perpendicular to the page of FIG. 1 than the through vias 114 for example, as suggested in part by the fact that through vias 115 are slightly “thicker” in an x direction, that is, in a horizontal direction.

According to some embodiments, the interconnect bridges 122 may include passive interconnect bridges, or active interconnect bridges. Thus, an interconnect bridge according to some embodiments may include active circuitry therein, or, it may not.

The panel layer 154 may have a multilayer configuration. In this case, a better warpage control effect may be obtained

Where bonding layers or bonding films are mentioned herein, they may include, for example, at least one of a thermosetting resin such as an epoxy resin, a thermoplastic resin such as polyimide, or a material including the thermosetting resin and the thermoplastic resin, a glass fiber, and/or a reinforcing material such as an inorganic filler, for example, prepreg (PPG), Ajinomoto Build-up Film (ABF), and the like.

Referring back to FIG. 1, the active electronic components 108, 116 and 118 may each be single-sided or double-sided. In this context, a double-sided die refers to a die that has connections on both surfaces. In some embodiments, a double-sided die may include through-silicon vias (TSVs) to form connections on both surfaces. The active surface of a double-sided die, which is the surface containing one or more active devices and a majority of interconnects, may face either direction depending on the design and electrical requirements. Although FIG. 1 shows the active electronic components 108, 116 and 118 in a particular arrangement, the dies 114 may be in any suitable arrangement.

Although the embodiment of FIG. 1 shows two interconnect bridges and three AECs, embodiments are not so limited, and include within their scope a microelectronic assembly including any number of interconnect bridges interconnecting any number of AECs.

As suggested previously, according to one embodiment, the microelectronic assembly 100 of FIG. 1 may be attached and electrically coupled to a package substrate, such as one including RDLs and possibly a core (organic or glass), or directly to a PCB or motherboard without the intermediary of a package substrate. Thus, substrate 104 may serve as an interposer that may allow a patch architecture-based coupling of the AECs that it supports to a package substrate, which may in turn be coupled to a circuit board via second level interconnects Thus, alternatively, substrate 104 may be coupled directly to a circuit board by second-level interconnects at the bottom surface thereof. The second-level interconnects may be any suitable second-level interconnects, including solder balls for a ball grid array arrangement, pins in a pin grid array arrangement or lands in a land grid array arrangement. The circuit board may be a motherboard, for example, and may have other components attached to it. The circuit board may include conductive pathways and other conductive contacts for routing power, ground, and signals through the circuit board, as known in the art.

Many of the elements of the semiconductor package 100 of FIG. 1 are included in other ones of the accompanying drawings relating to other embodiments, for example embodiments of FIGS. 2-4. A description of some elements may therefore not be repeated when discussing the drawings to be described below, and any of these elements may take any of the forms disclosed herein. Elements common as between FIGS. 1-4 may be indicated with same reference numerals.

FIG. 2 is a cross-sectional view of a microelectronic assembly 200 according to a second embodiment, where the panel layer and the interconnect bridges have substantially a same thickness. Microelectronic assembly 200 has substantially the same components as those shown and explained with respect to microelectronic assembly 100 of FIG. 1, except for the fact that, in the embodiment of microelectronic assembly 200, there is a substrate 204 (different from substrate 104 of FIG. 1), because substrate 204 includes a panel layer 254 similar to panel layer 154 of FIG. 1, but thinner. As a result, in FIG. 2, there is no need for a molding compound 146 that extends below a lower surface of the interconnect bridges 122, and hence no through vias 115 as there would be no need for the same. Instead, mold compound 246 in the embodiment of FIG. 2 is adjacent lateral walls of the interconnect bridges 122 in the openings 145, and stops substantially at a level of a lower surface of the interconnect bridges 122. FIG. 2 is an example of the suggestion above, namely that provision of a mold compound allows flexibility in the thickness of the glass panel of a substrate according to embodiments, in that the panel can be as thick as needed for manufacturability and/or supporting AECs thereon, while still allowing the embedding therein of interconnect bridges of smaller and possibly of varying thicknesses, as the mold will compensate for the thickness differences.

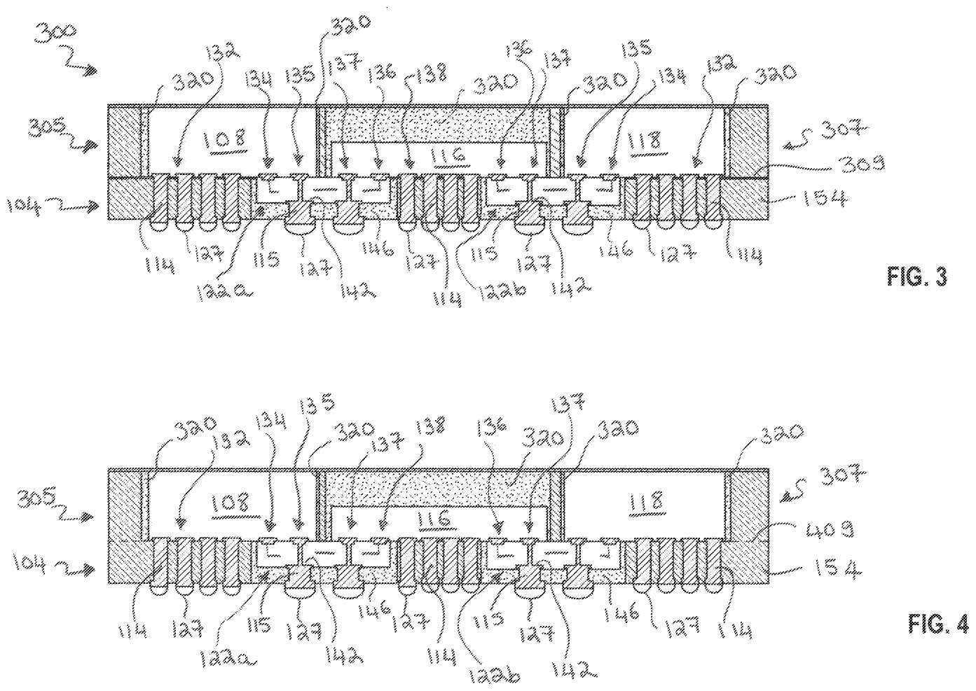

FIGS. 3 and 4 are respective cross-sectional views of microelectronic assembly 300 according to a third embodiment, and of microelectronic assembly 400 according to a fourth embodiment, respectively. The third and fourth embodiments in FIGS. 3 and 4, respectively, are similar to the first embodiment of FIG. 1, except that, in FIGS. 3 and 4, instead of a substantial non-AEC portion of the EC layer 305 being occupied by mold compound, the EC layer includes a glass material. In particular, in FIGS. 3 and 4, the AECs 108, 116 and 118 are within openings 355 (for AECs 108 and 118) and 357 (for AEC 116) of a glass layer 307, the glass layer 307 being on a top surface of substrate 104. EC layer 305 further includes mold compound 320 encompassing the AECs 108 and 118 at side walls thereof, and AEC 116 at side walls and at a top surface thereof. Otherwise, microelectronic assemblies 300 and 400 have substantially the same components as those shown and explained with respect to microelectronic assembly 100 of FIG. 1. The provision of a glass material in the EC layer imparts further structure stability and hence more reliable manufacturability to the microelectronic assemblies of FIGS. 3 and 4.

While microelectronic assembly 300 shows that the glass layer 307 is bonded to panel layer (that includes glass) 154 by way of an adhesive layer or bonding layer 309, microelectronic assembly 400 shows a fusion bonded interface 409 between the glass layer 307 and the glass panel layer 154.

Some embodiments, examples of which are shown in FIGS. 1-4, enable heterogenous integration utilizing a glass patch (panel layer) with hybrid bonded interconnects, where connections between the AEC and the underlying substrate (e.g., a package substrate or a circuit board such as a PCB or motherboard) are connections through the glass patch and through contacts at a bottom surface of the glass patch. These connections may advantageously be provided through high aspect ratio glass patterning techniques to achieve much finer contact pitches of about 25 microns or less for patch architectures in semiconductor fabrication.

Some embodiments make possible high interconnect density (low contact pitch) microelectronic assemblies based on patch architectures using a glass patch in the form of a glass panel layer. Some embodiments provide the ability to assemble together multiple AECs onto a single glass patch, connect the AECs through interconnect bridges embedded within the glass patch, so that the resulting microelectronic assembly is effectively disaggregated from an eventual package substrate, or circuit board (PCB or motherboard) to which the microelectronic assembly is to be attached. This results in easier manufacturability and higher yield. Some embodiments allow AEC assembly at a the device level in part because of the vertical disaggregation, meaning that AECs may first be integrated onto a patch, and then the patch packaged with an underlying substrate (package substrate, such as one with an organic or glass core and RDLs or a circuit board, such as a PCB or motherboard) no longer at the wafer level, but at the level of a singulated underlying substrate. Some embodiments take advantage of low total thickness variation (TTV) glass layers as patches with high aspect ratio (AR) patterning capability to carry electrically coupled AECs thereon.

Some embodiments include embedding an interconnect bridge with IBTVs therein (such as an EMIB-T) into an opening or cavity of a glass panel. Some embodiments include electrically coupling two AECs to one another through the interconnect bridge by way of hybrid bonding to the interconnect bridge contacts, such as copper to copper bonding, or by way of solder bonding. Where hybrid bonding is used, it may include bonding using pyrido[3,4-g]isoquinoline-5,10-dione (PID). Some embodiments include a microelectronic assembly that includes two glass patches attached together, either by way of a bonding film or by way of fusing the glass patches together, where one glass patch carries one or more interconnect bridges and another glass patch carries one or more AECs therein electrically coupled through the interconnect bridges. Some embodiments include a laser patterned glass patch where through vias in the glass patch provide connections between AECs to be coupled to the glass patch at an upper surface thereof, and an underlying substrate to be coupled to the glass patch at a bottom surface thereof.

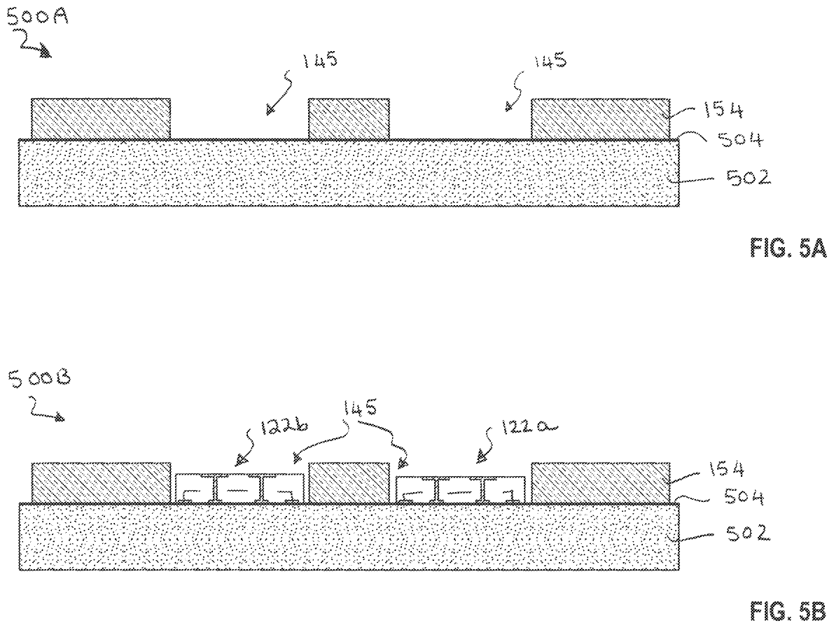

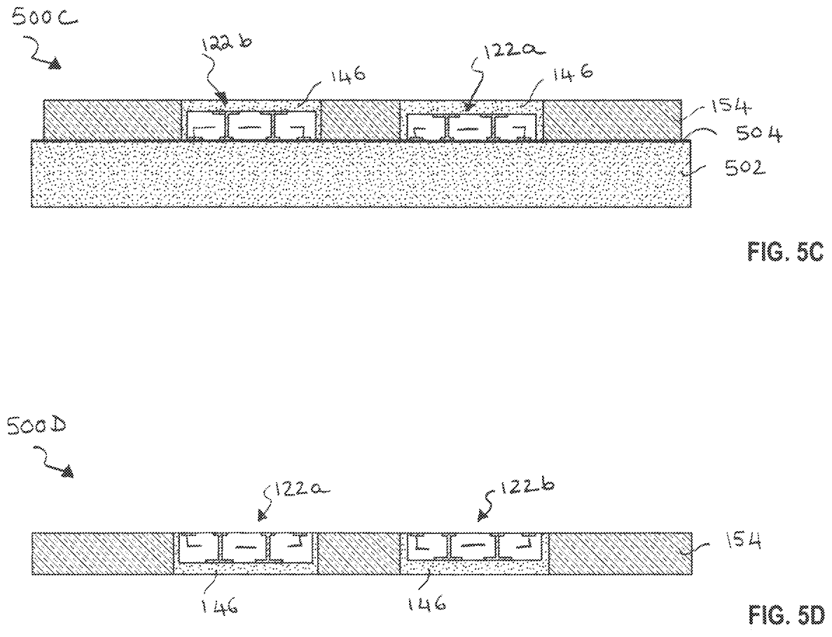

FIGS. 5A-5D show cross sectional views of temporary microelectronic configurations at various stages thereof to result in a configuration 500D that may be further processed for the fabrication of either microelectronic assembly 100 of FIG. 1 or microelectronic assembly 400 of FIG. 4 according to some embodiments.

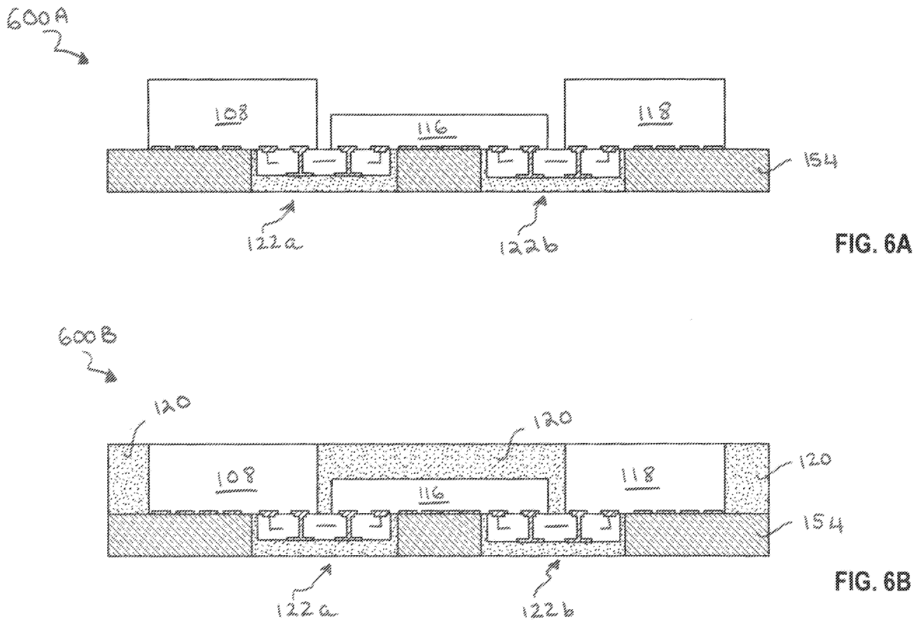

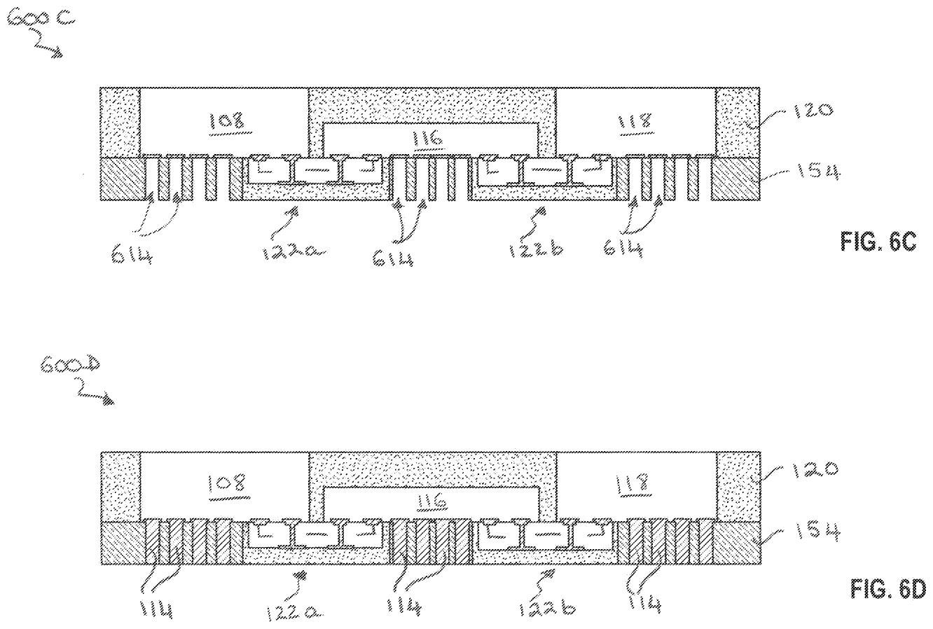

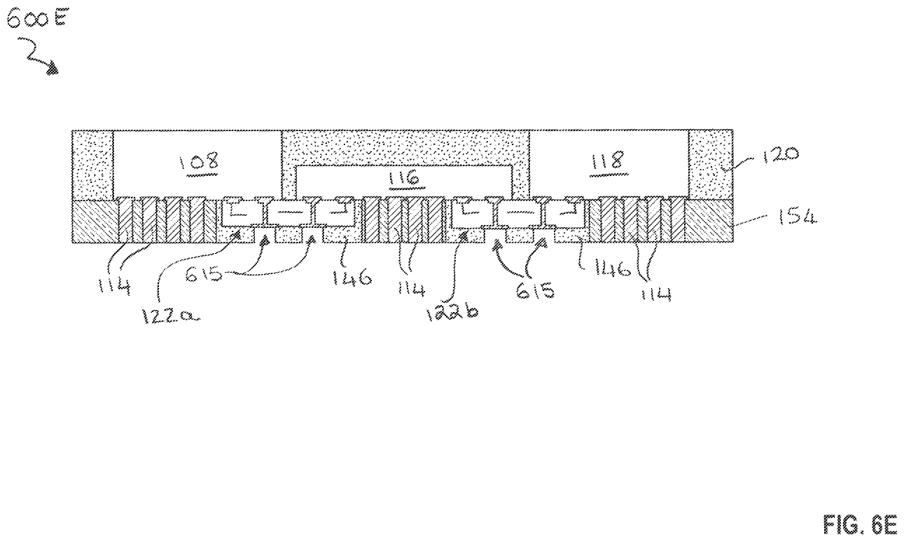

FIGS. 6A-6E show cross sectional views of temporary microelectronic configurations at various stages thereof, starting from the temporary microelectronic configuration 500D of FIG. 5D, for the fabrication of the microelectronic assembly 100 of Fig. q according to some embodiments.

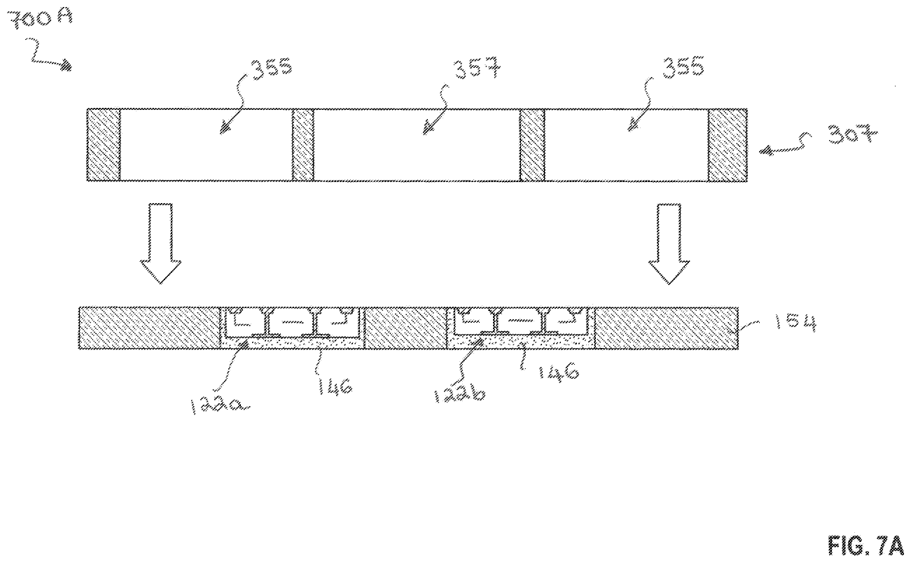

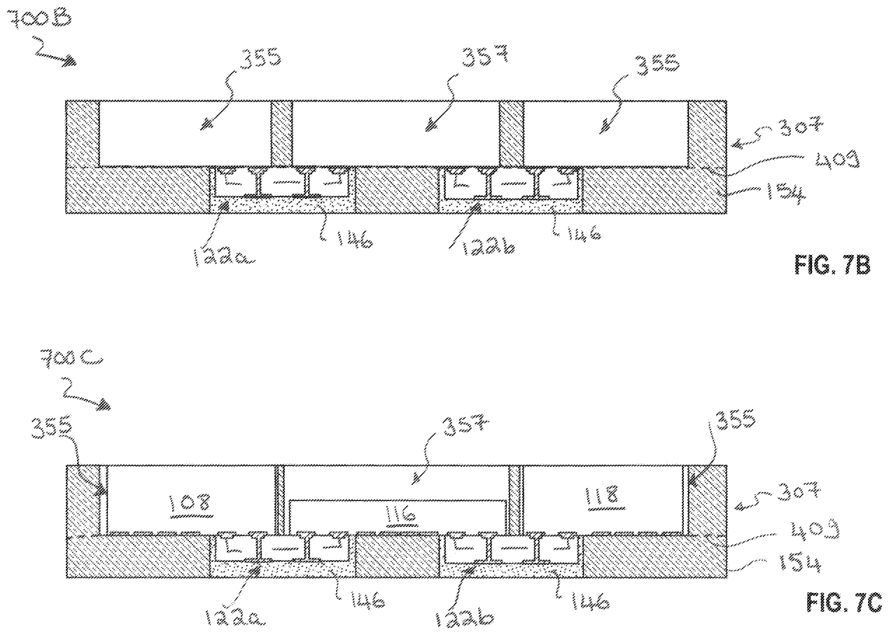

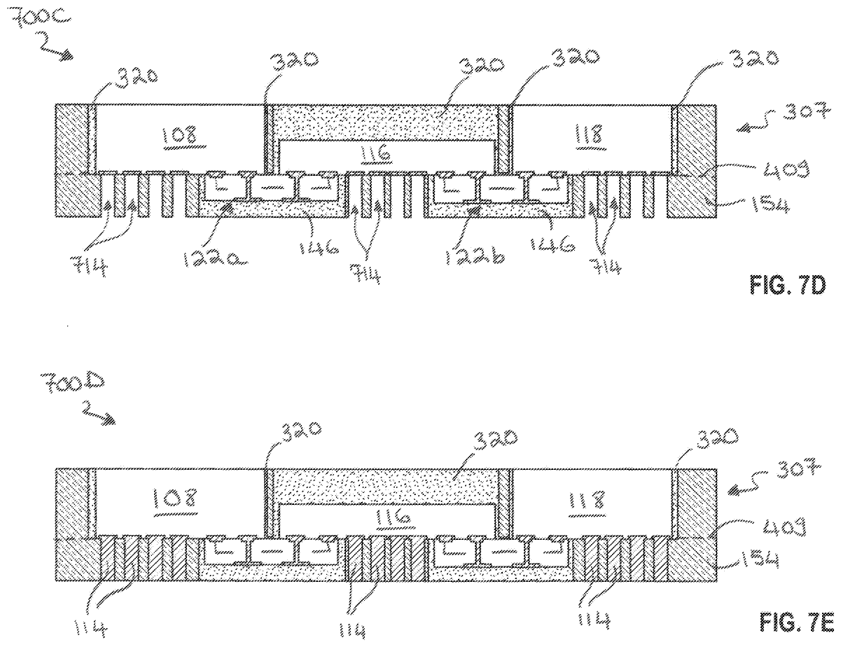

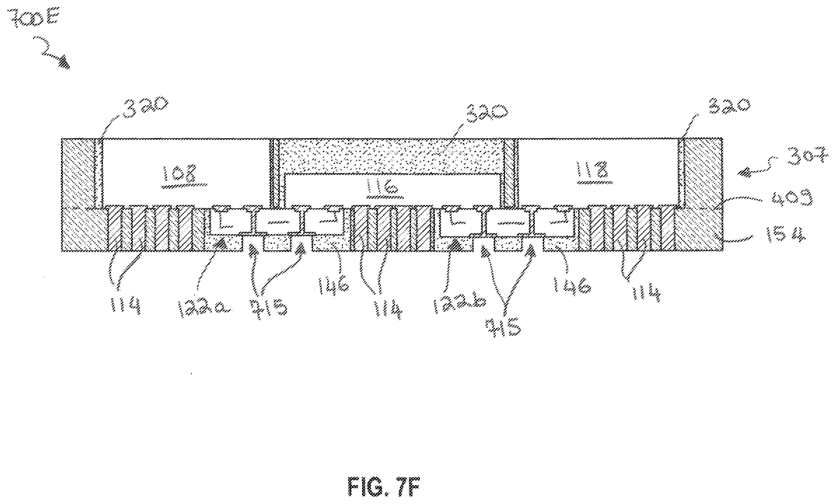

FIGS. 7A-7F show cross sectional views of temporary microelectronic configurations at various stages thereof, starting from the temporary microelectronic configuration 500D of FIG. 5D, for the fabrication of the microelectronic assembly 400 of FIG. 4 according to some embodiments.

Referring first to FIG. 5A, a temporary microelectronic configuration 500A includes a glass panel 154 patterned to have a desired thickness and two openings 145 therein. The openings 145 may be provided in glass panel 154 for example using laser etching of the glass material of glass panel 154. For example, etching using a laser sensitization technique may be performed, where regions of the glass that are to be provided with openings are first exposed to a laser beam, as a result of which the exposed glass material therein undergoes a phase change. The glass is then subjected to an wet etching process to which the phase changed regions of the glass are more sensitive. As a result, the phase changed regions can be etched away, leaving openings 145 with relatively smooth surfaces. The glass panel 154 may be secured on a temporary carrier 502, for example using a bonding layer 504.

Referring to FIG. 5B, a temporary microelectronic configuration 500B includes the glass panel 154 on the carrier 504, and, in addition, interconnect bridges 122a and 122b affixed temporarily onto the carrier 504 by way of the bonding layer 504. The interconnect bridges 122a and 122b are affixed within the openings 145 such that their upper surfaces (facing down in the figure) are substantially coextensive with an upper surface (facing down in the figure) of the glass panel 154.

Referring to FIG. 5C, a temporary microelectronic configuration 500C includes the glass panel 154 and the interconnect bridges 122 on the carrier 504. At FIG. 5C, a mold compound may be provided in the remaining spaces of the openings 145 surrounding the interconnect bridges, and then planarized to provide mold compound 146. Mold compound 146 is shown as encapsulating the interconnect bridges 122, and, in the shown embodiments, as extending on a lower surfaces (facing up in the figure) of the interconnect bridges. It can be seen from FIG. 5C that the provision of the mold compound allows the assembly of interconnect bridges and glass panels of differing thicknesses. In the shown embodiment, the mold compound 146 compensates for the thickness differential between the glass panel 154 and the interconnect bridges 146.

Referring to FIG. 5D, a temporary microelectronic configuration 500D includes the glass panel 154, the interconnect bridges 122 within openings 145, and the mold compound 146 encapsulating the interconnect bridges within openings 145. In FIG. 5D, the temporary microelectronic configuration 500D has been removed from the temporary carrier 504, and flipped over, such that the upper surfaces of the glass panel 154 and of the interconnect bridges face upward.

Temporary microelectronic configuration 500D of FIG. 5D may be further processed to yield the microelectronic assembly 100 of FIG. 1 (FIGS. 6A-6E) or the microelectronic assembly 400 of FIG. 4 (FIGS. 7A-7F).

Referring to FIG. 6A, a temporary microelectronic configuration 600A includes the temporary microelectronic configuration 500D of FIG. 5D, and further shows AECs 108, 116 and 118 electrically coupled to the glass panel 154 by being hybrid bonded thereto. The hybrid bonding provides a permanent bond that combines a dielectric bond (such as SiOx) with embedded metal (such as Cu) to form interconnections. It is referred to in the industry sometimes as direct bond interconnect (DBI). Hybrid bonding extends fusion bonding with embedded metal pads in the bond interface, which allows face-to-face connection in this example of AECs 108, 116 and 118 with the underlying contact pads of the glass panel and of the interconnect bridges.

Referring to FIG. 6B, a temporary microelectronic configuration 600B includes the microelectronic configuration 600A of FIG. 6A, along with a mold compound 120 provided to encapsulate the AECs 108, 116 and 118. The mold compound may be dispensed, cured, and then polished.

Referring to FIG. 6C, a temporary microelectronic configuration 600C includes the microelectronic configuration 600B of FIG. 6B, where through via holes 614 have been provided in glass panel 154. The through holes 614 may be provided using a laser sensitization technique as described above. Use of a glass panel allows the provision, for example through laser sensitization, of finer pitched (e.g., about 25 microns or less) through vias with higher aspect ratios than those that can be provided in silicon or in organic substrates, in this way allowing the provision of a patch architecture where there exists more flexibility in the thickness of the glass panel and hence less susceptibility to warpage of the same during manufacturing, while at the same time making possible the provision of fine pitched contacts in miniaturized patch architectures.

Referring to FIG. 6D, a temporary microelectronic configuration 600D includes the microelectronic configuration 600C of FIG. 6C, where the through vias holes have been filled with an electrically conductive material, such as copper, to provide the through vias 114. The electrically conductive material of the vias 114 may be provided by way of plating and polishing.

Referring to FIG. 6E, a temporary microelectronic configuration 600E includes the microelectronic configuration 600D of FIG. 6D, where through via holes 615 have been provided in the portion of the mold compound 146 that covers the lower surfaces of interconnect bridges 122. The through holes 615 may be provided for example by way of drilling.

Referring back to FIG. 1, the microelectronic configuration 100 of FIG. 1 includes the microelectronic configuration 600E of FIG. 6E, where (1) the through vias holes have been filled with an electrically conductive material, such as copper, to provide the through vias 115, (2) where contact pads 128 are provided at a bottom surface of vias 114 and 115, and (3) further where solder bumps 127 are provided on the contact pads 128. The electrically conductive material of the vias 115 may be provided by way of plating and polishing and/or a semi additive process. The electrically conductive material of contact pads 128 may be provided by way of plating and patterning and/or a semi additive process. The solder bumps 127 may be provided using a laser solder balling technique.

Let us now refer to FIGS. 7A-7F, which start off from the temporary microelectronic configuration 500D of FIG. 5D, and depict further processing stages to arrive at the configuration of the microelectronic assembly 400 of FIG. 4.

Referring to FIGS. 7A and 7B, the temporary microelectronic configuration 500D of FIG. 5D may be fusion bonded, as shown in exploded view 700A, to patterned glass layer 307. The patterned glass layer 307 is to house AECs 108, 116 and 118, and may be patterned in the same manner of glass panel 154 for the provision of openings 355 and 357 therein, for example using a laser sensitization technique. The resulting structure corresponds to temporary microelectronic assembly 700B of FIG. 7B which shows a fusion bonded interface 409 between glass panel 154 and glass layer 307.

Referring to FIG. 7C, a temporary microelectronic configuration 700C includes the temporary microelectronic configuration 700B of FIG. 7B, and further showing AECs 108, 116 and 118 placed in respective openings 355 and electrically coupled to the glass panel 154 by being hybrid bonded thereto.

Referring to FIG. 7D, a temporary microelectronic configuration 700D includes the microelectronic configuration 700C of FIG. 7C, along with a mold compound 320 provided to encapsulate the AECs 108, 116 and 118. The mold compound may be dispensed, cured, and then polished. In addition, in FIG. 7D, through via holes 714 have been provided in glass panel 154. The through holes 714 may be provided using a laser sensitization technique as described above.

Referring to FIG. 7E, a temporary microelectronic configuration 700E includes the microelectronic configuration 700D of FIG. 7D, where the through vias holes have been filled with an electrically conductive material, such as copper, to provide the through vias 114. The electrically conductive material of the vias 114 may be provided by way of plating and polishing.

Referring to FIG. 7F, a temporary microelectronic configuration 700F includes the microelectronic configuration 700E of FIG. 7E, where through via holes 715 have been provided in the portion of the mold compound 146 that covers the lower surfaces of interconnect bridges 122. The through holes 715 may be provided for example by way of drilling.

Referring back to FIG. 4, the microelectronic configuration 100 of FIG. 4 includes the microelectronic configuration 700E of FIG. 7E, where (1) the through vias holes have been filled with an electrically conductive material, such as copper, to provide the through vias 115, (2) where contact pads 128 are provided at a bottom surface of vias 114 and 115, and (3) further where solder bumps 127 are provided on the contact pads 128. The electrically conductive material of the vias 115 may be provided by way of plating and polishing and/or a semi additive process. The electrically conductive material of contact pads 128 may be provided by way of plating and patterning and/or a semi additive process. The solder bumps 127 may be provided using a laser solder balling technique.

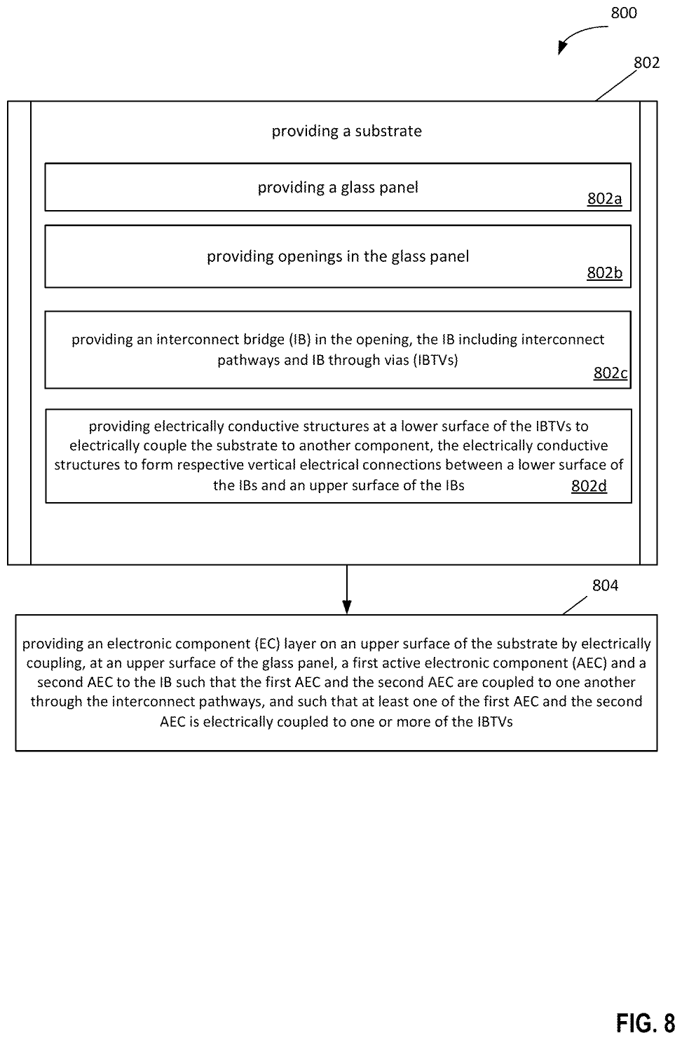

FIG. 8 is a flowchart of a process 800 according to some embodiments. At operation 802, the process includes providing a substrate. Providing a substrate includes, at operation 802a, providing a glass panel; at operation 802b, providing an opening in the glass panel; at operation 802c, providing an interconnect bridge (IB) in the opening, the IB including interconnect pathways and IB through vias (IBTVs); and at operation 802d, providing electrically conductive structures at a lower surface of the IBTVs to electrically couple the substrate to another component, the electrically conductive structures to form respective vertical electrical connections between a lower surface of the IBs and an upper surface of the IBs. At operation 804, the process 800 includes providing an electronic component (EC) layer on an upper surface of the substrate by electrically coupling, at an upper surface of the glass panel, a first active electronic component (AEC) and a second AEC to the IB such that the first AEC and the second AEC are coupled to one another through the interconnect pathways, and such that at least one of the first AEC and the second AEC is electrically coupled to one or more of the IBTVs.

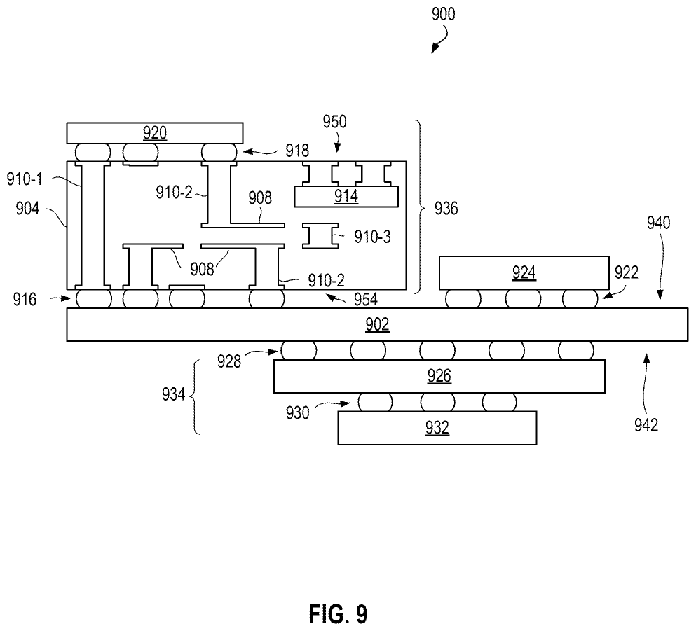

FIG. 9 is a cross-sectional side view of an integrated circuit device assembly 900 that may include one or more integrated circuit structures each including any of the microelectronic assemblies such as semiconductor packages of embodiments described herein. The integrated circuit device assembly 900 includes a number of components disposed on a circuit board 902 (which may be a motherboard, system board, mainboard, etc.). The integrated circuit device assembly 900 includes components disposed on a first face 940 of the circuit board 902 and an opposing second face 942 of the circuit board 902; generally, components may be disposed on one or both faces 940 and 942. Any of the integrated circuit components discussed below with reference to the integrated circuit device assembly 900 may include an integrated circuit structure including an interconnect structure as described herein.

In some embodiments, the circuit board 902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 902. In other embodiments, the circuit board 902 may be a non-PCB substrate. The integrated circuit device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (as shown in FIG. 9), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 936 may include an integrated circuit component 920 coupled to an interposer 904 by coupling components 918. The coupling components 918 may take any suitable form for the application, such as the forms discussed above with reference to the coupling components 916. Although a single integrated circuit component 920 is shown in FIG. 9, multiple integrated circuit components may be coupled to the interposer 904; indeed, additional interposers may be coupled to the interposer 904. The interposer 904 may provide an intervening substrate used to bridge the circuit board 902 and the integrated circuit component 920.

The integrated circuit component 920 may be a packaged or unpackaged integrated circuit product that includes one or more integrated circuit dies. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 920, a single monolithic integrated circuit die comprises solder bumps attached to contacts on the die. The solder bumps allow the die to be directly attached to the interposer 904. The integrated circuit component 920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 920 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 904 may spread connections to a wider pitch or reroute a connection to a different connection. For example, the interposer 904 may couple the integrated circuit component 920 to a set of ball grid array (BGA) conductive contacts of the coupling components 916 for coupling to the circuit board 902. In the embodiment illustrated in FIG. 9, the integrated circuit component 920 and the circuit board 902 are attached to opposing sides of the interposer 904; in other embodiments, the integrated circuit component 920 and the circuit board 902 may be attached to a same side of the interposer 904. In some embodiments, three or more components may be interconnected by way of the interposer 904.

In some embodiments, the interposer 904 may be formed as a PCB, including multiple metal layers separated from one another by layers of dielectric material and interconnected by electrically conductive vias. In some embodiments, the interposer 904 may be formed of an epoxy resin, a fiberglass-reinforced epoxy resin, an epoxy resin with inorganic fillers, a ceramic material, or a polymer material such as polyimide. In some embodiments, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through hole vias 910-1 (that extend from a first face 950 of the interposer 904 to a second face 954 of the interposer 904), blind vias 910-2 (that extend from the first or second faces 950 or 954 of the interposer 904 to an internal metal layer), and buried vias 910-3 (that connect internal metal layers).

In some embodiments, the interposer 904 can comprise a silicon interposer. Through silicon vias (TSV) extending through the silicon interposer can connect connections on a first face of a silicon interposer to an opposing second face of the silicon interposer. In some embodiments, an interposer 904 comprising a silicon interposer can further comprise one or more routing layers to route connections on a first face of the interposer 904 to an opposing second face of the interposer 904.

The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art. In embodiments where the interposer is a non-printed circuit board

The integrated circuit device assembly 900 may include an integrated circuit component 924 coupled to the first face 940 of the circuit board 902 by coupling components 922. The coupling components 922 may take the form of any of the embodiments discussed above with reference to the coupling components 916, and the integrated circuit component 924 may take the form of any of the embodiments discussed above with reference to the integrated circuit component 920.

The integrated circuit device assembly 900 illustrated in FIG. 9 includes a package-on-package structure 934 coupled to the second face 942 of the circuit board 902 by coupling components 928. The package-on-package structure 934 may include an integrated circuit component 926 and an integrated circuit component 932 coupled together by coupling components 930 such that the integrated circuit component 926 is disposed between the circuit board 902 and the integrated circuit component 932. The coupling components 928 and 930 may take the form of any of the embodiments of the coupling components 916 discussed above, and the integrated circuit components 926 and 932 may take the form of any of the embodiments of the integrated circuit component 920 discussed above. The package-on-package structure 934 may be configured in accordance with any of the package-on-package structures known in the art.

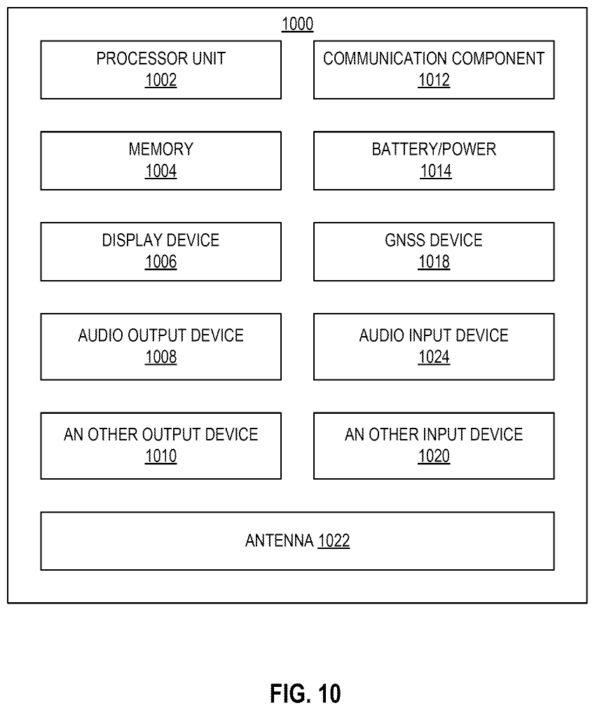

FIG. 10 is a block diagram of an example electrical device 1000 that may include one or more of the embodiment semiconductor packages disclosed herein. For example, any suitable ones of the components of the electrical device 1000 may include one or more of the integrated circuit device assemblies 900, integrated circuit components 920, and/or embodiment semiconductor packages disclosed herein. A number of components are illustrated in FIG. 10 as included in the electrical device 1000, but any one or more of these components may be omitted or duplicated, as suitable for the application. In some embodiments, some or all of the components included in the electrical device 1000 may be attached to one or more motherboards mainboards, or system boards. In some embodiments, one or more of these components are fabricated onto a single system-on-a-chip (SoC) die.

Additionally, in various embodiments, the electrical device 1000 may not include one or more of the components illustrated in FIG. 10, but the electrical device 1000 may include interface circuitry for coupling to the one or more components. For example, the electrical device 1000 may not include a display device 1006, but may include display device interface circuitry (e.g., a connector and driver circuitry) to which a display device 1006 may be coupled. In another set of examples, the electrical device 1000 may not include an audio input device 1024 or an audio output device 1008, but may include audio input or output device interface circuitry (e.g., connectors and supporting circuitry) to which an audio input device 1024 or audio output device 1008 may be coupled.

The electrical device 1000 may include one or more processor units 1002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the processor unit 1002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1000 can comprise one or more processor units 1002 that are heterogeneous or asymmetric to another processor unit 1002 in the electrical device 1000. There can be a variety of differences between the processing units 1002 in a system in terms of a spectrum of metrics of merit including architectural, microarchitectural, thermal, power consumption characteristics, and the like. These differences can effectively manifest themselves as asymmetry and heterogeneity among the processor units 1002 in the electrical device 1000.

In some embodiments, the electrical device 1000 may include a communication component 1012 (e.g., one or more communication components). For example, the communication component 1012 can manage wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electrical device 1000 may include one or more antennas, such as antenna 1022 to facilitate wireless communications and/or to receive other wireless communications (such as AM or FM radio transmissions).

In some embodiments, the communication component 1012 may manage wired communications, such as electrical, optical, or any other suitable communication protocols (e.g., IEEE 802.3 Ethernet standards). As noted above, the communication component 1012 may include multiple communication components. For instance, a first communication component 1012 may be dedicated to shorter-range wireless communications such as Wi-Fi or Bluetooth, and a second communication component 1012 may be dedicated to longer-range wireless communications such as global positioning system (GPS), EDGE, GPRS, CDMA, WiMAX, LTE, EV-DO, or others. In some embodiments, a first communication component 1012 may be dedicated to wireless communications, and a second communication component 1012 may be dedicated to wired communications.

The electrical device 1000 may include battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any embedded or wired or wirelessly connected external device that generates an audible indicator, such speakers, headsets, or earbuds.

The electrical device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electrical device 1000 may include a Global Navigation Satellite System (GNSS) device 1018 (or corresponding interface circuitry, as discussed above), such as a Global Positioning System (GPS) device. The GNSS device 1018 may be in communication with a satellite-based system and may determine a geolocation of the electrical device 1000 based on information received from one or more GNSS satellites, as known in the art.

The electrical device 1000 may include another output device 1010 (or corresponding interface circuitry, as discussed above). Examples of the other output device 1010 may include an audio codec, a video codec, a printer, a wired or wireless transmitter for providing information to other devices, or an additional storage device.

The electrical device 1000 may include another input device 1020 (or corresponding interface circuitry, as discussed above). Examples of the other input device 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1000 may be any other electronic device that processes data. In some embodiments, the electrical device 1000 may comprise multiple discrete physical components. Given the range of devices that the electrical device 1000 can be manifested as in various embodiments, in some embodiments, the electrical device 1000 can be referred to as a computing device or a computing system.

FIG. 10 is a flow chart of a process 1000 according to some embodiments. At operation 1002, the process includes providing a plurality of first dies. At operation 1004, the process includes providing an encapsulation layer on the first dies to form first layer of the semiconductor subassembly. At operation 1006, the process includes providing a first dielectric layer over the first layer to form a first layer and first dielectric layer subassembly. At operation 1008, the process includes providing a passive heat spreader interposer. At operation 1010, the process includes providing a second dielectric layer on the passive heat spreader interposer to form a passive heat spreader interposer and second dielectric layer subassembly. At operation 1012, the process includes forming an interface layer between and mechanically bonding the passive heat spreader interposer and the first layer, the interface layer providing a direct dielectric-to-dielectric bond including a first dielectric sublayer directly adjacent the first layer and formed from the first dielectric layer, and a second dielectric sublayer directly adjacent the first dielectric sublayer, formed from the second dielectric layer, and including an amorphous material. At operation 1014, the process includes providing a second layer including a substrate. At operation 1016, the process includes electrically coupling the substrate to the first dies.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of embodiments has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

In embodiments, the phrase “A is located on B” means that at least a part of A is in direct physical contact or indirect physical contact (having one or more other features between A and B) with at least a part of B.

In the instant description, “A is adjacent to B” means that at least part of A is in direct physical contact with at least a part of B.

In the instant description, “B is between A and C” means that at least part of B is in or along a space separating A and C and that the at least part of B is in direct or indirect physical contact with A and C.

In the instant description, “A is attached to B” means that at least part of A is mechanically attached to at least part of B, either directly or indirectly (having one or more other features between A and B).

In the instant description, “the As are coupled to the Bs” means that at least some of the As are coupled to at least some of the Bs, and not necessarily that all As are coupled to at least one B and all Bs are coupled to at least one A.

In the instant description, “A is within B” means that at least some of A is encompassed within the physical boundaries of B.

The use of reference numerals separated by a “/”, such as “102/104” for example, is intended to refer to 102 or 104 as appropriate. Otherwise, the forward slash (“/”) as used herein means “and/or.”

When used to describe a range of dimensions, the phrase “between X and Y” represents a range that includes X and Y. For convenience, the phrase “FIG. 2” may be used to refer to the collection of drawings of FIGS. 2A-2C, the phrase “FIG. 5” may be used to refer to the collection of drawings of FIGS. 5A-5I, etc. Although certain elements may be referred to in the singular herein, such elements may include multiple sub-elements. For example, “an insulating material” may include one or more insulating materials. As used herein, a “conductive contact” may refer to a portion of conductive material (e.g., metal) serving as an electrical interface between different components; conductive contacts may be recessed in, flush with, or extending away from a surface of a component, and may take any suitable form (e.g., a conductive pad or socket, or portion of a conductive line or via).

The use of the techniques and structures provided herein can be detected using tools such as: electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, such tools can indicate an integrated circuit including at least one semiconductor package including an embedded magnetic inductor.

In some embodiments, the techniques, processes and/or methods described herein can be detected based on the structures formed therefrom. In addition, in some embodiments, the techniques and structures described herein can be detected based on the benefits derived therefrom. Numerous configurations and variations will be apparent in light of this disclosure.

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “according to some embodiments,” “in accordance with embodiments,” or “in embodiments,” which may each refer to one or more of the same or different embodiments. Furthermore, the terms “comprising,” “including,” “having,” and the like, as used with respect to embodiments of the present disclosure, are synonymous.

“Coupled” as used herein means that two or more elements are in direct physical contact, or that that two or more elements indirectly physically contact each other, but yet still cooperate or interact with each other (i.e. one or more other elements are coupled or connected between the elements that are said to be coupled with each other). The term “directly coupled” means that two or more elements are in direct contact.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 107 Siemens per meter (S/m) at 20 degrees Celsius. Examples of such materials include Cu, Ag, Al, Au, W, Zn and Ni.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices. The term “signal” may refer to at least one current signal, voltage signal, magnetic signal, or data/clock signal. The meaning of “a,” “an,” and “the” include plural references. The meaning of “in” includes “in” and “on.”

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner, and are not intended to imply that the objects so described must necessarily be made of different materials or have different dimensions.

For purposes of the embodiments, any transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BICMOS, CMOS, eFET, etc., may be used without departing from the scope of the disclosure. The term “MN” indicates an n-type transistor (e.g., nMOS, NPN BJT, etc.) and the term “MP” indicates a p-type transistor (e.g., pMOS, PNP BJT, etc.).

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

### EXAMPLES

Some non-limiting example embodiments are set forth below.

Example 1 includes a microelectronic assembly comprising: a substrate including: a panel including glass and defining an opening therein; an interconnect bridge (IB) in the opening and including interconnect pathways and IB through vias (IBTVs); and electrically conductive structures at a lower surface of the substrate to electrically couple the substrate to another component, at least some of the electrically conductive structures coupled to the IBTVs to form respective vertical electrical connections between the lower surface of the substrate and an upper surface of the substrate; and an electronic component (EC) layer on the upper surface of the substrate, the EC layer including a first active EC (AEC) and a second AEC electrically coupled to one another through the interconnect pathways, at least one of the first AEC or the second AECs further electrically coupled to one or more of the at least some of the electrically conductive structures.

Example 2 includes the subject matter of Example 1, wherein an upper surface of the IB is substantially coextensive with an upper surface of the panel.

Example 3 includes the subject matter of Example 1, wherein the first AEC and the second AEC have different heights with respect to one another.

Example 4 includes the subject matter of any one of Examples 1-3, wherein the substrate includes a mold compound encapsulating the IB, and wherein the at least some of the electrically conductive structures include mold through vias extending from the lower surface of the substrate toward the IBTVs.

Example 5 includes the subject matter of any one of Examples 1-3, wherein a lower surface of the IB is substantially coextensive with the lower surface of the substrate, and wherein the at least some of the electrically conductive structures include contact pads on the IBTVs.

Example 6 includes the subject matter of any one of Examples 1-5, wherein the panel includes panel through vias (PTVs) extending from the lower surface of the substrate to an upper surface of the substrate, the first AEC and the second AEC further electrically coupled to the PTVs.

Example 7 includes the subject matter of Example 6, wherein the first AEC and the second AEC are electrically coupled to the substrate by being hybrid bonded thereto.

Example 8 includes the subject matter of Example 7, wherein substrate includes contact pads on upper surfaces of corresponding ones of the IBTVs and of the PTVs, wherein the first AEC and the second AEC include contact pads on lower surfaces thereof, and wherein the first AEC and the second AEC are hybrid bonded to the substrate such that respective hybrid bonded pairs of the contact pads define hybrid bonding layers therebetween with metal grain interdiffusion of one or more metal materials of the contact pads.

Example 9 includes the subject matter of any one of Examples 1-8, the EC layer including a mold compound encapsulating the first AEC and the second AEC.

Example 10 includes the subject matter of any one of Examples 1-8, wherein the EC layer includes a glass layer defining openings therein, the first AEC and the second AEC in one or more of the openings of the glass layer.

Example 11 includes the subject matter of Example 10, wherein the glass layer and the panel of the substrate define a glass to glass fusion bonding interface therebetween.

Example 12 includes the subject matter of Example 10, further including a bonding film between the glass layer and the panel of the substrate.

Example 13 includes the subject matter of Example 1, wherein the substrate further includes one or more redistribution layers on a lower surface thereof.

Example 14 includes the subject matter of any one of Examples 1-13, wherein the electrically conductive structures include contact pads and solder balls on the contact pads.

Example 15 includes the subject matter of Example 1, wherein the opening is a first opening, the IB is a first IB, the interconnect pathways are first interconnect pathways, the IBTVs are first IBTVs, and the vertical electrical connections are first vertical electrical connections, and wherein: the substrate defines a second opening therein and includes a second IB in the second opening, the second IB including second interconnect pathways and second IBTVs; some of the electrically conductive structures are coupled to the second IBTVs to from second respective vertical electrical connections between the lower surface of the substrate and the upper surface of the substrate; the EC layer includes a third AEC electrically coupled to the second AEC through the second interconnect pathways; and at least one of the second AEC and the third AEC are electrically coupled to one or more of said some of the electrically conductive structures.

Example 16 includes a microelectronic package comprising: a package substrate including a plurality of redistribution layers, the redistribution layer including dielectric layers and electrically conductive layers between the dielectric layers; and a microelectronic assembly including: a substrate including: a panel including glass and defining an opening therein; an interconnect bridge (IB) in the opening and including interconnect pathways and IB through vias (IBTVs); and electrically conductive structures at a lower surface of the substrate to electrically couple the substrate to the package substrate, at least some of the electrically conductive structures coupled to the IBTVs to form respective vertical electrical connections between the lower surface of the substrate and an upper surface of the substrate; and an electronic component (EC) layer on the upper surface of the substrate, the EC layer including a first active EC (AEC) and a second AEC electrically coupled to one another through the interconnect pathways, at least one of the first AEC or the second AECs further electrically coupled to one or more of the at least some of the electrically conductive structures.

Example 17 includes the subject matter of Example 16, wherein an upper surface of the IB is substantially coextensive with an upper surface of the panel.

Example 18 includes the subject matter of Example 16, wherein the first AEC and the second AEC have different heights with respect to one another.

Example 19 includes the subject matter of any one of Examples 16-18, wherein the substrate includes a mold compound encapsulating the IB, and wherein the at least some of the electrically conductive structures include mold through vias extending from the lower surface of the substrate toward the IBTVs.

Example 20 includes the subject matter of any one of Examples 16-18, wherein a lower surface of the IB is substantially coextensive with the lower surface of the substrate, and wherein the at least some of the electrically conductive structures include contact pads on the IBTVs.

Example 21 includes the subject matter of any one of Examples 16-20, wherein the panel includes panel through vias (PTVs) extending from the lower surface of the substrate to an upper surface of the substrate, the first AEC and the second AEC further electrically coupled to the PTVs.

Example 22 includes the subject matter of Example 21, wherein the first AEC and the second AEC are electrically coupled to the substrate by being hybrid bonded thereto.

Example 23 includes the subject matter of Example 22, wherein substrate includes contact pads on upper surfaces of corresponding ones of the IBTVs and of the PTVs, wherein the first AEC and the second AEC include contact pads on lower surfaces thereof, and wherein the first AEC and the second AEC are hybrid bonded to the substrate such that respective hybrid bonded pairs of the contact pads define hybrid bonding layers therebetween with metal grain interdiffusion of one or more metal materials of the contact pads.

Example 24 includes the subject matter of any one of Examples 16-23, the EC layer including a mold compound encapsulating the first AEC and the second AEC.

Example 25 includes the subject matter of any one of Examples 16-23, wherein the EC layer includes a glass layer defining openings therein, the first AEC and the second AEC in one or more of the openings of the glass layer.

Example 26 includes the subject matter of Example 25, wherein the glass layer and the panel of the substrate define a glass to glass fusion bonding interface therebetween.

Example 27 includes the subject matter of Example 25, further including a bonding film between the glass layer and the panel of the substrate.

Example 28 includes the subject matter of Example 16, wherein the substrate further includes one or more redistribution layers on a lower surface thereof.

Example 29 includes the subject matter of any one of Examples 16-28, wherein the electrically conductive structures include contact pads and solder balls on the contact pads.

Example 30 includes the subject matter of Example 16, wherein the opening is a first opening, the IB is a first IB, the interconnect pathways are first interconnect pathways, the IBTVs are first IBTVs, and the vertical electrical connections are first vertical electrical connections, and wherein: the substrate defines a second opening therein and includes a second IB in the second opening, the second IB including second interconnect pathways and second IBTVs; some of the electrically conductive structures are coupled to the second IBTVs to from second respective vertical electrical connections between the lower surface of the substrate and the upper surface of the substrate; the EC layer includes a third AEC electrically coupled to the second AEC through the second interconnect pathways; and at least one of the second AEC and the third AEC are electrically coupled to one or more of said some of the electrically conductive structures.

Example 31 includes an integrated circuit (IC) device assembly comprising: a circuit board including one of a printed circuit board or a motherboard; and a microelectronic package including: a package substrate including a plurality of redistribution layers, the redistribution layer including dielectric layers and electrically conductive layers between the dielectric layers, the package substrate electrically coupled at a lower surface thereof to the circuit board; and a microelectronic assembly electrically coupled to the package substrate and including: a substrate including: a panel including glass and defining an opening therein; an interconnect bridge (IB) in the opening and including interconnect pathways and IB through vias (IBTVs); and electrically conductive structures at a lower surface of the substrate to electrically couple the substrate to another component, at least some of the electrically conductive structures coupled to the IBTVs to form respective vertical electrical connections between the lower surface of the substrate and an upper surface of the substrate; and an electronic component (EC) layer on the upper surface of the substrate, the EC layer including a first active EC (AEC) and a second AEC electrically coupled to one another through the interconnect pathways, at least one of the first AEC or the second AECs further electrically coupled to one or more of the at least some of the electrically conductive structures.

Example 32 includes the subject matter of Example 31, wherein an upper surface of the IB is substantially coextensive with an upper surface of the panel.

Example 33 includes the subject matter of Example 31, wherein the first AEC and the second AEC have different heights with respect to one another.

Example 34 includes the subject matter of any one of Examples 31-33, wherein the substrate includes a mold compound encapsulating the IB, and wherein the at least some of the electrically conductive structures include mold through vias extending from the lower surface of the substrate toward the IBTVs.

Example 35 includes the subject matter of any one of Examples 31-33, wherein a lower surface of the IB is substantially coextensive with the lower surface of the substrate, and wherein the at least some of the electrically conductive structures include contact pads on the IBTVs.

Example 36 includes the subject matter of any one of Examples 31-35, wherein the panel includes panel through vias (PTVs) extending from the lower surface of the substrate to an upper surface of the substrate, the first AEC and the second AEC further electrically coupled to the PTVs.

Example 37 includes the subject matter of Example 36, wherein the first AEC and the second AEC are electrically coupled to the substrate by being hybrid bonded thereto.

Example 38 includes the subject matter of Example 37, wherein substrate includes contact pads on upper surfaces of corresponding ones of the IBTVs and of the PTVs, wherein the first AEC and the second AEC include contact pads on lower surfaces thereof, and wherein the first AEC and the second AEC are hybrid bonded to the substrate such that respective hybrid bonded pairs of the contact pads define hybrid bonding layers therebetween with metal grain interdiffusion of one or more metal materials of the contact pads.

Example 39 includes the subject matter of any one of Examples 31-38, the EC layer including a mold compound encapsulating the first AEC and the second AEC.

Example 40 includes the subject matter of any one of Examples 31-38, wherein the EC layer includes a glass layer defining openings therein, the first AEC and the second AEC in one or more of the openings of the glass layer.

Example 41 includes the subject matter of Example 40, wherein the glass layer and the panel of the substrate define a glass to glass fusion bonding interface therebetween.

Example 42 includes the subject matter of Example 40, further including a bonding film between the glass layer and the panel of the substrate.

Example 43 includes the subject matter of Example 31, wherein the substrate further includes one or more redistribution layers on a lower surface thereof.

Example 44 includes the subject matter of any one of Examples 31-43, wherein the electrically conductive structures include contact pads and solder balls on the contact pads.

Example 45 includes the subject matter of Example 31, wherein the opening is a first opening, the IB is a first IB, the interconnect pathways are first interconnect pathways, the IBTVs are first IBTVs, and the vertical electrical connections are first vertical electrical connections, and wherein: the substrate defines a second opening therein and includes a second IB in the second opening, the second IB including second interconnect pathways and second IBTVs; some of the electrically conductive structures are coupled to the second IBTVs to from second respective vertical electrical connections between the lower surface of the substrate and the upper surface of the substrate; the EC layer includes a third AEC electrically coupled to the second AEC through the second interconnect pathways; and at least one of the second AEC and the third AEC are electrically coupled to one or more of said some of the electrically conductive structures.

Example 46 includes a method of fabricating a microelectronic assembly, comprising: providing a substrate including providing a glass panel; providing an opening in the glass panel; providing an interconnect bridge (IB) in the opening, the IB including interconnect pathways and IB through vias (IBTVs); and providing electrically conductive structures at a lower surface of the IBTVs to electrically couple the substrate to another component, the electrically conductive structures to form respective vertical electrical connections between a lower surface of the IBs and an upper surface of the IBs; and providing an electronic component (EC) layer on an upper surface of the substrate by electrically coupling, at an upper surface of the glass panel, a first active electronic component (AEC) and a second AEC to the IB such that the first AEC and the second AEC are coupled to one another through the interconnect pathways, and such that at least one of the first AEC and the second AEC is electrically coupled to one or more of the IBTVs.

Example 47 includes the subject matter of Example 46, wherein an upper surface of the IB is substantially coextensive with an upper surface of the panel.

Example 48 includes the subject matter of Example 46, wherein the first AEC and the second AEC have different heights with respect to one another.

Example 49 includes the subject matter of any one of Examples 46-48, further including encapsulating the IB with a mold compound, wherein providing the electrically conductive structures including providing mold through vias extending from the lower surface of the substrate toward the lower surface of the IBTVs.

Example 50 includes the subject matter of any one of Examples 46-48, wherein a lower surface of the IB is substantially coextensive with the lower surface of the substrate, and wherein the electrically conductive structures include contact pads on the IBTVs.

Example 51 includes the subject matter of any one of Examples 46-50, further including providing panel through vias (PTVs) extending from the lower surface of the substrate to an upper surface of the substrate, and electrically coupling the first AEC and the second AEC to the PTVs.

Example 52 includes the subject matter of Example 51, wherein electrically coupling the first AEC and the second AEC to the IB includes hybrid bonding contacts of the first AEC and contacts of the second AEC, respectively, to contacts of the IB.

Example 53 includes the subject matter of any one of Examples 46-52, wherein providing the EC layer further includes providing a mold compound to encapsulate the first AEC and the second AEC.

Example 54 includes the subject matter of any one of Examples 46-52, wherein the openings are first openings, and wherein providing the EC layer includes providing a glass layer defining second openings therein, and placing the first AEC and the second AEC in one or more of the second openings of the glass layer.

Example 55 includes the subject matter of Example 54, further including fusion bonding the glass layer and the glass panel to one another.

Example 56 includes the subject matter of Example 54, further including adhering the glass layer to the glass panel by way of a bonding film.

Example 57 includes the subject matter of Example 46, wherein the substrate further includes one or more redistribution layers on a lower surface thereof.

Example 58 includes the subject matter of any one of Examples 46-57, wherein the electrically conductive structures include contact pads and solder balls on the contact pads.

Example 59 includes the subject matter of Example 46, wherein the opening is a first opening, the IB is a first IB, the interconnect pathways are first interconnect pathways, the IBTVs are first IBTVs, the electrically conductive structures are first electrically conductive structures, and the vertical electrical connections are first vertical electrical connections, the method further including: providing a second opening in the glass panel; providing a second IB in the second opening, the second IB including second interconnect pathways and second IBTVs; electrically coupling second electrically conductive structures to the second IBTVs to from second respective vertical electrical connections between the lower surface of the substrate and the upper surface of the substrate; and electrically coupling, at an upper surface of the glass panel, the second AEC and a third AEC to the second IB such that the second AEC and the third AEC are coupled to one another through the second interconnect pathways, and such that at least one of the second AEC and the third AEC is electrically coupled to one or more of the second IBTVs.

Example 60 includes the subject matter of any one of Examples 1, 16, 31 or 46, wherein the first AEC and the second AEC include respective photonics integrated circuits (PICs); and the EC layer includes: a glass material; and optical waveguides coupling the PICs to one another through the glass material of the EC layer for signal communication between the PICs.

What is claimed is:

1. A microelectronic assembly comprising:
a substrate including:
a panel including glass and defining an opening therein;
an interconnect bridge (IB) in the opening and including interconnect pathways and IB through vias (IBTVs); and
electrically conductive structures at a lower surface of the substrate to electrically couple the substrate to another component, at least some of the electrically conductive structures coupled to the IBTVs to form respective vertical electrical connections between the lower surface of the substrate and an upper surface of the substrate; and
an electronic component (EC) layer on the upper surface of the substrate, the EC layer including a first active EC (AEC) and a second AEC electrically coupled to one another through the interconnect pathways, at least one of the first AEC or the second AECs further electrically coupled to one or more of the at least some of the electrically conductive structures.

2. The microelectronic assembly of claim 1, wherein an upper surface of the IB is substantially coextensive with an upper surface of the panel.

3. The microelectronic assembly of claim 1, wherein the substrate includes a mold compound encapsulating the IB, and wherein the at least some of the electrically conductive structures include mold through vias extending from the lower surface of the substrate toward the IBTVs.

4. The microelectronic assembly of claim 1, wherein a lower surface of the IB is substantially coextensive with the lower surface of the substrate, and wherein the at least some of the electrically conductive structures include contact pads on the IBTVs.

5. The microelectronic assembly of claim 1, wherein the panel includes panel through vias (PTVs) extending from the lower surface of the substrate to an upper surface of the substrate, the first AEC and the second AEC further electrically coupled to the PTVs.

6. The microelectronic assembly of claim 5, wherein the first AEC and the second AEC are electrically coupled to the substrate by being hybrid bonded thereto.

7. The microelectronic assembly of claim 6, wherein substrate includes contact pads on upper surfaces of corresponding ones of the IBTVs and of the PTVs, wherein the first AEC and the second AEC include contact pads on lower surfaces thereof, and wherein the first AEC and the second AEC are hybrid bonded to the substrate such that respective hybrid bonded pairs of the contact pads define hybrid bonding layers therebetween with metal grain interdiffusion of one or more metal materials of the contact pads.

8. The microelectronic assembly of claim 1, the EC layer including a mold compound encapsulating the first AEC and the second AEC.

9. The microelectronic assembly of claim 1, wherein the EC layer includes a glass layer defining openings therein, the first AEC and the second AEC in one or more of the openings of the glass layer.

10. The microelectronic assembly of claim 9, wherein the glass layer and the panel of the substrate define a glass to glass fusion bonding interface therebetween.

11. The microelectronic assembly of claim 9, further including a bonding film between the glass layer and the panel of the substrate.

12. The microelectronic assembly of claim 1, wherein the electrically conductive structures include contact pads and solder balls on the contact pads.

13. The microelectronic assembly of claim 1, wherein the opening is a first opening, the IB is a first IB, the interconnect pathways are first interconnect pathways, the IBTVs are first IBTVs, and the vertical electrical connections are first vertical electrical connections, and wherein:
the substrate defines a second opening therein and includes a second IB in the second opening, the second IB including second interconnect pathways and second IBTVs;
some of the electrically conductive structures are coupled to the second IBTVs to from second respective vertical electrical connections between the lower surface of the substrate and the upper surface of the substrate;
the EC layer includes a third AEC electrically coupled to the second AEC through the second interconnect pathways; and
at least one of the second AEC and the third AEC are electrically coupled to one or more of said some of the electrically conductive structures.

14. A microelectronic package comprising:
a package substrate including a plurality of redistribution layers, the redistribution layer including dielectric layers and electrically conductive layers between the dielectric layers; and
a microelectronic assembly including:
a substrate including:
a panel including glass and defining an opening therein;
an interconnect bridge (IB) in the opening and including interconnect pathways and IB through vias (IBTVs); and
electrically conductive structures at a lower surface of the substrate to electrically couple the substrate to the package substrate, at least some of the electrically conductive structures coupled to the IBTVs to form respective vertical electrical connections between the lower surface of the substrate and an upper surface of the substrate; and
an electronic component (EC) layer on the upper surface of the substrate, the EC layer including a first active EC (AEC) and a second AEC electrically coupled to one another through the interconnect pathways, at least one of the first AEC or the second AECs further electrically coupled to one or more of the at least some of the electrically conductive structures.

15. The microelectronic package of claim 14, wherein an upper surface of the IB is substantially coextensive with an upper surface of the panel, and wherein the first AEC and the second AEC have different heights with respect to one another.

16. The microelectronic package of claim 14, wherein the panel includes panel through vias (PTVs) extending from the lower surface of the substrate to an upper surface of the substrate, the first AEC and the second AEC further electrically coupled to the PTVs.

17. The microelectronic package of claim 16, wherein the first AEC and the second AEC are electrically coupled to the substrate by being hybrid bonded thereto.

18. The microelectronic package of claim 17, wherein substrate includes contact pads on upper surfaces of corresponding ones of the IBTVs and of the PTVs, wherein the first AEC and the second AEC include contact pads on lower surfaces thereof, and wherein the first AEC and the second AEC are hybrid bonded to the substrate such that respective hybrid bonded pairs of the contact pads define hybrid bonding layers therebetween with metal grain interdiffusion of one or more metal materials of the contact pads.

19. A method of fabricating a microelectronic assembly, comprising:
providing a substrate including
providing a glass panel;
providing an opening in the glass panel;
providing an interconnect bridge (IB) in the opening, the IB including interconnect pathways and IB through vias (IBTVs); and
providing electrically conductive structures at a lower surface of the IBTVs to electrically couple the substrate to another component, the electrically conductive structures to form respective vertical electrical connections between a lower surface of the IBs and an upper surface of the IBs; and
providing an electronic component (EC) layer on an upper surface of the substrate by electrically coupling, at an upper surface of the glass panel, a first active electronic component (AEC) and a second AEC to the IB such that the first AEC and the second AEC are coupled to one another through the interconnect pathways, and such that at least one of the first AEC and the second AEC is electrically coupled to one or more of the IBTVs.

20. The method of claim 19, wherein electrically coupling the first AEC and the second AEC to the IB includes hybrid bonding contacts of the first AEC and contacts of the second AEC, respectively, to contacts of the IB.
